(19) United States
(12) Patent Application Publication
(10) Pub. No.: US 2016/0336937 A1
(43) Pub. Date: Nov. 17, 2016

(54) METHOD FOR ELECTRICAL SWITCHING IN OXIDE SEMICONDUCTOR DEVICE

(71) Applicant: Pukyong National University Industry-University Cooperation Foundation, Busan (KR)

(72) Inventors: Yongwook Lee, Busan (KR); Jihoon Kim, Gyungsangnam-do (KR)

(21) Appl. No.: 14/801,828

(22) Filed: Jul. 17, 2015

(30) Foreign Application Priority Data
May 15, 2015 (KR) 10-2015-0068155

(51) Int. Cl. H03K 17/78

(52) U.S. Cl. CPC H03K 17/78

(57) ABSTRACT

A method for electrical switching in an oxide semiconductor device is disclosed. The method includes applying a bias voltage to an oxide thin film of the semiconductor device, the semiconductor device having the oxide thin film formed on a substrate and two terminals formed at both ends of the oxide thin film, and controlling on-off switching of the semiconductor device by irradiating a carbon dioxide (CO₂) laser to the oxide thin film, while the bias voltage is applied.

This application claims the benefit of Korean Patent Application No. 10-2015-0068155, filed on May 15, 2015, which is hereby incorporated by reference as if fully set forth herein.

### BACKGROUND OF THE INVENTION

1. Field of the Invention

The present invention generally relates to a method for electrical switching in an oxide semiconductor device, and more particularly, to a method for performing electrical switching in an oxide semiconductor device by irradiating a carbon dioxide (CO₂) laser beam to a vanadium dioxide (VO₂) thin film.

2. Discussion of the Related Art

An electrical gating-based power switching semiconductor, which is a core device used for a high-power inverter attracting attention recently, such as a high voltage DC transmission system and a flexible AC transmission system, needs a plurality of additional circuits and an auxiliary power source, for monitoring and triggering. As a result, the electrical gating-based power switching semiconductor is likely to malfunction.

In contrast, an optical gating-based power switching semiconductor does not need additional circuits and eliminates the risk of short circuit due to its material insulation. Accordingly, optical gating is attracting much interest as a next-generation power switching technique.

Besides a fixed high-power system, a switching device is also required for a large number of medium-power and low-power systems such as a train or an electric vehicle and a device having a high efficiency, a high switching speed, and a low risk of malfunction is required. Since battery capacity cannot be increased indefinitely particularly for an electrical vehicle due to limitations of battery technology, a high-efficiency power device is needed. Considering that the malfunction of the power device may lead to an incident, there is a need for developing a device capable of highly reliable electrical switching.

### SUMMARY OF THE INVENTION

Accordingly, the present invention is directed to a method for electrical switching in an oxide semiconductor device that substantially obviates one or more problems due to limitations and disadvantages of the related art.

An object of the present invention is to provide an electrical switching method for an oxide semiconductor device, which obviates the need for an additional circuit, eliminates an incident cause such as short circuit, and enables fast switching.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for electrical switching in an oxide semiconductor device includes applying a bias voltage to an oxide thin film of the semiconductor device, the semiconductor device having the oxide thin film formed on a substrate and two terminals formed at both ends of the oxide thin film, and controlling on-off switching of the semiconductor device by irradiating a carbon dioxide (CO₂) laser to the oxide thin film, while the bias voltage is applied.

The oxide thin film may be a vanadium dioxide (VO₂) thin film.

The CO₂ laser may have a wavelength ranging from 10.57 μm to 10.63 μm.

Bidirectional switching may be controlled by switching on the oxide semiconductor device during irradiation of the CO₂ laser to the oxide thin film and switching off the oxide semiconductor device during non-irradiation of the CO₂ laser to the oxide thin film.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a flowchart illustrating an electrical switching method in an oxide semiconductor device according to an embodiment of the present invention;

FIG. 2 is a diagram illustrating a system for testing the electrical switching method in an oxide semiconductor device according to the embodiment of the present invention;

FIG. 3 is a graph illustrating current-voltage characteristics (I-V characteristics) in relation to the electrical switching method in an oxide semiconductor device according to the embodiment of the present invention;

FIG. 4 is a graph illustrating the result of a first simulation of the electrical switching method in an oxide semiconductor device according to the embodiment of the present invention;

FIG. 5 is a graph illustrating the result of a second simulation of the electrical switching method in an oxide semiconductor device according to the embodiment of the present invention;

FIG. 6 is a graph illustrating the result of a third simulation of the electrical switching method in an oxide semiconductor device according to the embodiment of the present invention;

FIG. 7 is a graph illustrating the result of a fourth simulation of the electrical switching method in an oxide semiconductor device according to the embodiment of the present invention;

FIG. 8 is a graph illustrating the result of a fifth simulation of the electrical switching method in an oxide semiconductor device according to the embodiment of the present invention;

FIG. 9 is a graph illustrating the result of a sixth simulation of the electrical switching method in an oxide semiconductor device according to the embodiment of the present invention;

FIG. 10 is a graph illustrating the result of a seventh simulation of the electrical switching method in an oxide semiconductor device according to the embodiment of the present invention; and

FIG. 11 is a graph illustrating the result of an eighth simulation of the electrical switching method in an oxide semiconductor device according to the embodiment of the present invention.

### DETAILED DESCRIPTION OF THE INVENTION

The objects and effects of the present invention and technical structures to achieve them will become apparent to those having ordinary skill in the art upon examination of the following embodiments of the present invention described with reference to the attached drawings. A detailed description of known functions or constructions will be omitted lest it should obscure the subject matter of the present invention. Terms used herein are defined in consideration of structures, roles, and functions according to the present invention and may be changed according to the intention of a user or an operator or customs.

However, the present invention is not limited to the embodiments described below. Rather, the present invention may be implemented in many other ways. The embodiments of the present invention are provided to make the disclosure of the present invention comprehensive and give a comprehensive scope of the present invention to those skilled in the art. The present invention is defined by the scope of the claims and the definition should be made based on the comprehensive contents of the present specification.

As used in the present disclosure, terms such as “includes” or “may include” refer to the presence of the corresponding component and is not intended to exclude one or more additional components, unless otherwise specified.

Now, a detailed description will be given of preferred embodiments of the present invention with reference to the attached drawings.

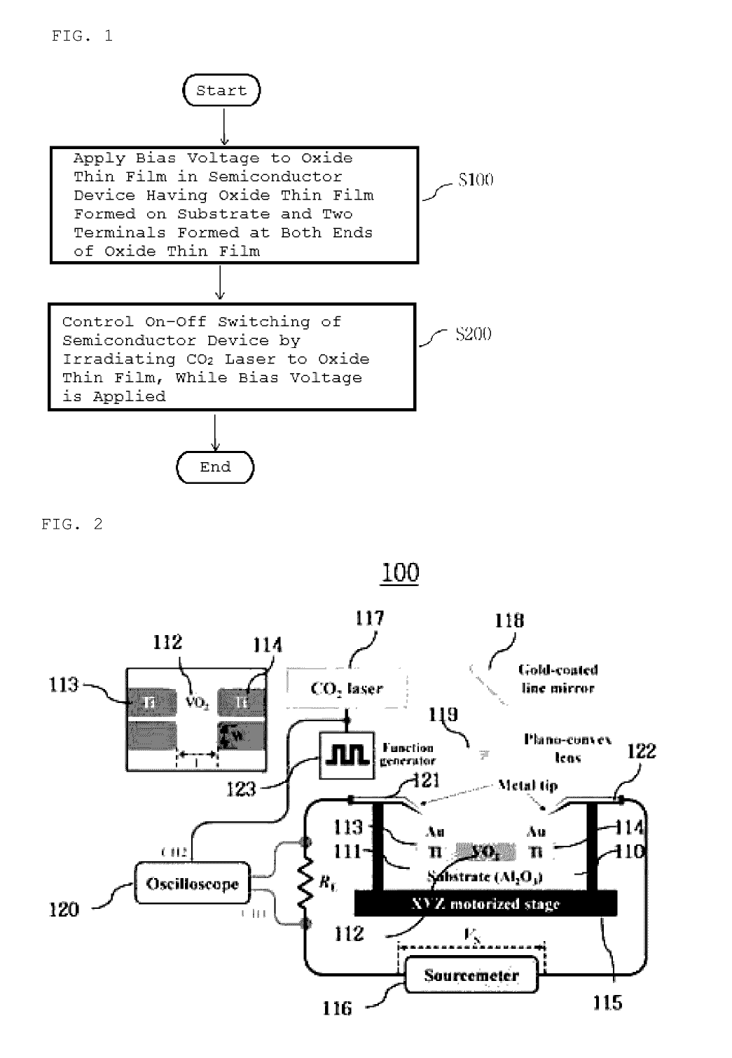

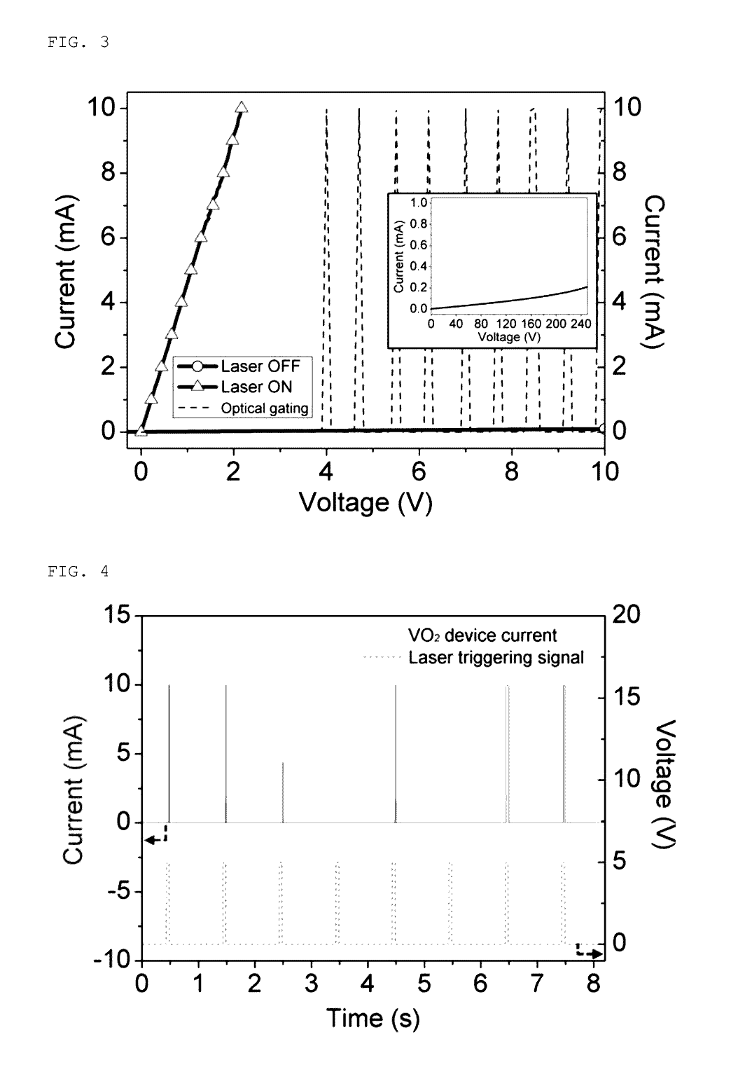

FIG. 1 is a flowchart illustrating an electrical switching method in an oxide semiconductor device according to an embodiment of the present invention, and FIG. 2 is a diagram illustrating a system for testing the electrical switching method in an oxide semiconductor device according to the embodiment of the present invention.

Referring to FIGS. 1 and 2, an oxide semiconductor device 110 is formed by forming an oxide thin film 112 on a substrate 111 and forming two terminals 113 and 114 at both ends of the oxide thin film 112. The two terminals 113 and 114 may be connected to both ends of the oxide thin film 112 and formed into titanium-gold electrodes.

The oxide thin film 112 may be formed of any oxide semiconductor material as far as the oxide semiconductor material is capable of electrical switching. Preferably, the oxide thin film 112 may be a vanadium dioxide (VO₂) thin film.

In an electrical switching method in an oxide semiconductor device according to an embodiment of the present invention, a temperature bias is applied to the two terminals 113 and 114 at both ends of the oxide thin film 112 of the oxide semiconductor device 110 (S100). Then, on/off switching of the oxide semiconductor device 110 is controlled by irradiating a carbon dioxide (CO₂) laser 117 to the oxide thin film 112, with the bias voltage applied (S200).

The electrical switching method in the oxide semiconductor device 110 according to the embodiment of the present invention is tested as follows.

The oxide semiconductor device 110 is aligned and disposed on a stage 115. The two terminals 113 and 114 at both ends of the oxide thin film 112, a resistor R_{E}, and a source meter 116 are connected serially and the source meter 116 is used as a voltage source for applying a DC bias voltage V.

With the bias voltage Vₛ applied, a laser beam is irradiated using the CO₂ laser 117. Herein, the optical path of the laser beam is switched by means of a gold-coated mirror 118 and the optical path-switched laser beam is focused onto the oxide thin film 112 through a plano-convex lens 119.

Metal tips 121 and 122 electrically contact the two terminals 113 and 114, respectively. An oscilloscope 120 is electrically connected to both ends of the resistor R_{E} and the CO₂ laser 117 and the waveform of an electrical signal is monitored through the oscilloscope 120.

A function generator 123 is electrically connected to the CO₂ laser 117, generates a pulse waveform, and provides the pulse waveform to the CO₂ laser 117.

The CO₂ laser 117 operates according to the pulse waveform received from the function generator 123 and irradiates a laser beam onto the oxide thin film 112 according to the pulse waveform.

FIG. 3 is a graph illustrating current-voltage characteristics (I-V characteristics) in relation to the electrical switching method in an oxide semiconductor device according to the embodiment of the present invention. FIG. 3 is a graph of I-V characteristics of a VO₂ thin film, illustrating results measured in current (I) mode. The current (I) mode is a current controlling mode and the characteristics curve of FIG. 3 illustrates current-voltage measurements achieved by controlling current applied to the VO₂ thin film.

In FIG. 3, a red solid line and red triangles represent an I-V characteristics curve of the VO₂ thin film, when the CO₂ laser 117 is turned on, and a black solid line and circles represent an I-V characteristics curve of the VO₂ thin film, when the CO₂ laser 117 is turned off. A graph interposed in FIG. 3 illustrates an I-V characteristics curve of the VO₂ thin film, when the CO₂ laser 117 does not emit a laser beam.

In FIG. 3, a blue dotted line represents results of bidirectional switching performed by turning on and off the CO₂ laser 117 nine times randomly, while applying a current of 10 mA to both ends of the terminals and increasing the bias voltage Vₛ from 3.9 V to 10 V. Bidirectional switching refers to switching on and off of the oxide semiconductor device 110 by triggering the CO₂ laser 117 so that on-switching may occur during irradiation of the CO₂ laser 117 and off-switching may occur during non-irradiation of the CO₂ laser 117.

Referring to FIG. 3, 10 mA of the applied current is measured at the bias voltage Vₛ between 3.9 V to 9.2 V, while the CO₂ laser 117 is turned on and off nine times. This implies that stable bidirectional switching through the irradiation of CO₂ laser 117 is performed at the bias voltage Vₛ between 3.9 V to 9.2 V.

As noted from FIG. 3, bidirectional on-off switching in the oxide semiconductor device is performed fast due to the photo-thermal effect of a laser beam of irradiated CO₂ laser 117.

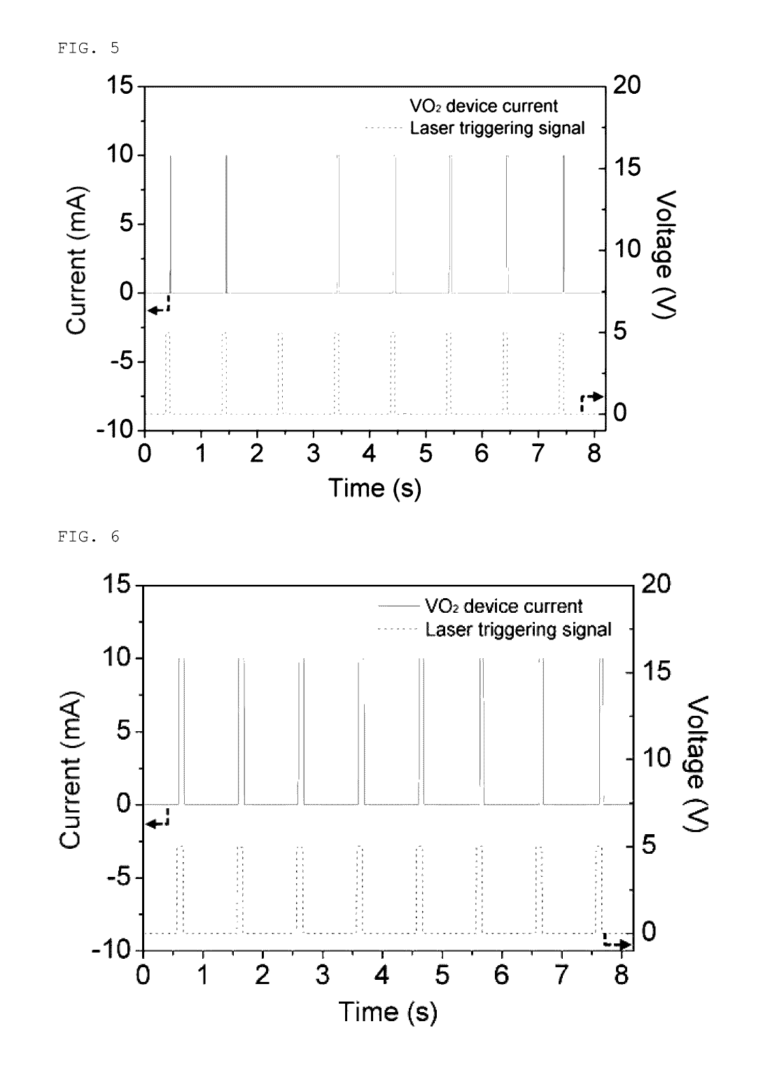

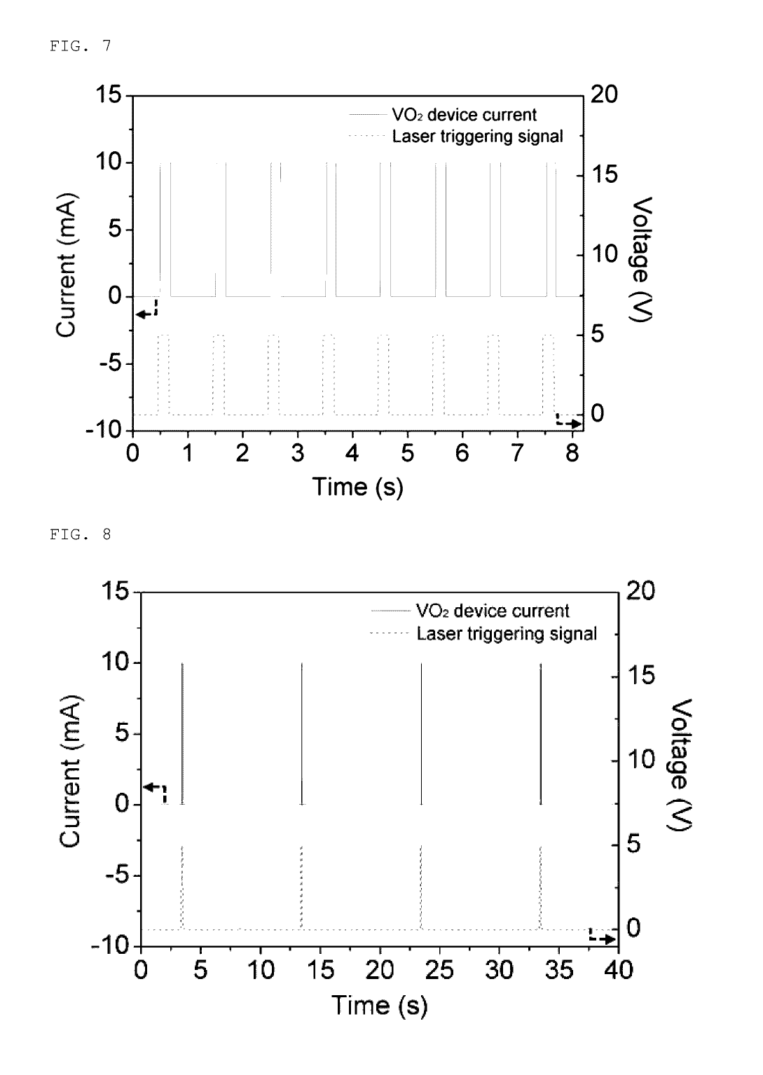

FIG. 4 is a graph illustrating the result of a first simulation of the electrical switching method in an oxide semiconductor device according to the embodiment of the present invention, FIG. 5 is a graph illustrating the result of a second simulation of the electrical switching method in an oxide semiconductor device according to the embodiment of the present invention, FIG. 6 is a graph illustrating the result of a third simulation of the electrical switching method in an oxide semiconductor device according to the embodiment of the present invention, and FIG. 7 is a graph illustrating the result of a fourth simulation of the electrical switching method in an oxide semiconductor device according to the embodiment of the present invention.

Specifically, FIGS. 4 to 7 are graphs illustrating CO₂ laser triggering signals and current responses of the oxide semiconductor device over time under the condition that the bias voltage Vₛ is 4.6 V, the value of the resistor R_{E} is 100Ω, a check current is 10 mA, and a pulse waveform has pulse widths of 50 ms, 70 ms, 100 ms, and 200 ms, respectively.

Referring to FIGS. 4 to 7, it is noted that bidirectional switching is unstable below a pulse width of 100 ms under the above condition. Accordingly, there is a need for adjusting the pulse width of a CO₂ laser triggering signal in order to achieve stable bidirectional switching.

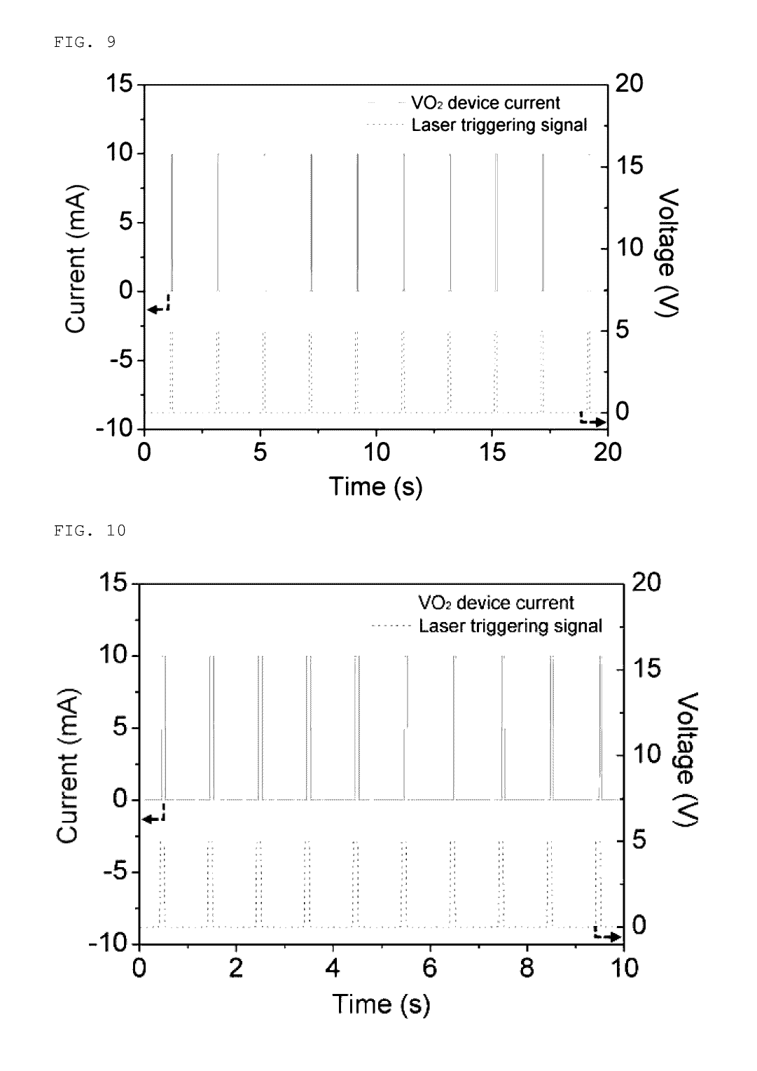

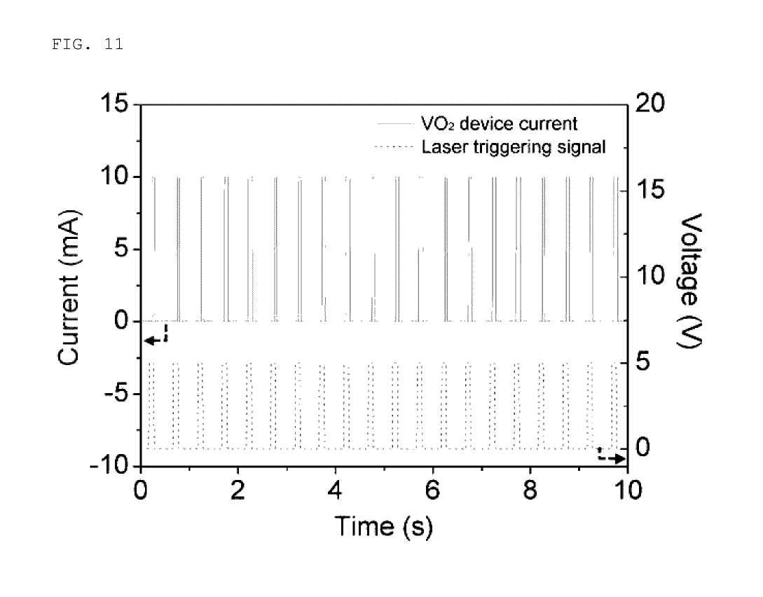

FIG. 8 is a graph illustrating the result of a fifth simulation of the electrical switching method in an oxide semiconductor device according to the embodiment of the present invention, FIG. 9 is a graph illustrating the result of a sixth simulation of the electrical switching method in an oxide semiconductor device according to the embodiment of the present invention, FIG. 10 is a graph illustrating the result of a seventh simulation of the electrical switching method in an oxide semiconductor device according to the embodiment of the present invention, and FIG. 11 is a graph illustrating the result of an eighth simulation of the electrical switching method in an oxide semiconductor device according to the embodiment of the present invention.

Specifically, FIGS. 8 to 11 are graphs illustrating CO₂ laser triggering signals and current responses of the oxide semiconductor device over time under the condition that the bias voltage Vₛ is 4.6 V, the value of the resistor R_{E} is 100Ω, a check current is 10 mA, a pulse waveform has a pulse width of 100 ms, and a CO₂ laser triggering signal is set to repetition periods of 0.1, 0.5, 1, and 2 Hz, respectively.

Referring to FIGS. 8 to 11, it is noted that bidirectional switching is stable at a pulse width of 100 ms. The rising and falling times of the check current were measured as 39 ms and 21 ms, respectively, which means very fast on-off switching.

As is apparent from the foregoing description of the method for electrical switching in an oxide semiconductor device according to an embodiment of the present invention, electrical switching of the semiconductor device is controlled by irradiating a carbon dioxide (CO₂) laser to the oxide thin film and triggering is performed by irradiating light onto an active region of a device. As a result, an additional circuit is not needed and thus the structure of the semiconductor device can be simplified.

Further, a power source is perfectly separated from a gating circuit. Therefore, an incident cause such as short circuit is fundamentally eliminated. The resulting decrease of malfunction can increase system reliability.

In addition, fast electrical switching can be performed in the oxide semiconductor device by generating much heat instantaneously in the device.

Those skilled in the art will appreciate that the present invention may be carried out in other specific ways than those set forth herein without departing from the spirit and essential characteristics of the present invention. The above embodiments are therefore to be construed in all aspects as illustrative and not restrictive. The scope of the invention should be determined by the appended claims and their legal equivalents, not by the above description, and all changes coming within the meaning and equivalency range of the appended claims are intended to be embraced therein.

What is claimed is:

1. A method for electrical switching in an oxide semiconductor device, the method comprising:
applying a bias voltage to an oxide thin film of the semiconductor device, the semiconductor device having the oxide thin film formed on a substrate and two terminals formed at both ends of the oxide thin film; and
controlling on-off switching of the semiconductor device by irradiating a carbon dioxide (CO₂) laser to the oxide thin film, while the bias voltage is applied.

2. The method according to claim 1, wherein the oxide thin film is a vanadium dioxide (VO₂) thin film.

3. The method according to claim 1, wherein the CO₂ laser has a wavelength ranging from 10.57 μm to 10.63 82 m.

4. The method according to claim 1, wherein bidirectional switching is controlled by switching on the oxide semiconductor device during irradiation of the CO₂ laser to the oxide thin film and switching off the oxide semiconductor device during non-irradiation of the CO₂ laser to the oxide thin film.
